(19) United States
(12) Patent Application Publication
(10) Pub. No.: US 2019/0378907 A1
(43) Pub. Date: Dec. 12, 2019

(54) TRANSISTOR GATE STRUCTURE, AND MANUFACTURING METHOD THEREFOR

(71) Applicant: Shanghai Huali Integrated Circuit Mfg. Co., Ltd., Shanghai (CN)

(72) Inventors: Shiming WANG, Shanghai (CN); Zhanyuan HU, Shanghai (CN); Zhiseng HUANG, Shanghai (CN)

(21) Appl. No.: 16/191,461

(22) Filed: Nov. 15, 2018

(30) Foreign Application Priority Data
Jun. 7, 2018 (CN) 201810580617.3

(51) Int. Cl. H01L 29/49; H01L 21/28

(52) U.S. Cl. CPC H01L 29/4966; H01L 21/28088

(57) ABSTRACT

The present disclosure provides a transistor gate structure and a manufacturing method for the transistor gate structure. The transistor gate structure is located on a substrate, the gate structure being isolated from the substrate by a gate insulating layer, and the gate structure comprises a work function layer and a plurality of sets of composite barrier layers located between the work function layer and the gate insulating layer, and each set of the plurality of sets of composite barrier layers comprise laminated first and second barrier layers, the material of the first barrier layer being different from that of the second barrier layer. By forming a plurality of sets of alternately laminated first and second barrier layers, a superior barrier effect can be achieved and the stability of the electric characteristics of a device can be improved.

### CROSS-REFERENCES TO RELATED APPLICATIONS

The present application claims priority to Chinese Patent Application No. 201810580617.3, filed on Jun. 7, 2018, entitled “TRANSISTOR GATE STRUCTURE, AND MANUFACTURING METHOD THEREFOR”, which is incorporated by reference herein for all purposes.

### TECHNICAL FIELD

The present disclosure relates to the field of semiconductors, and particularly to a semiconductor transistor gate structure and a manufacturing method for the gate structure.

### BACKGROUND OF THE DISCLOSURE

Since the disclosure of integrated circuits by Dr. Jack Kilby of Texas Instruments in early years, scientists and engineers have made numerous disclosures and improvements in semiconductor devices and processes. Over 50 years, the dimension of semiconductors have been significantly reduced, which translates into an increasing processing speed and decreasing power consumption. To date, the development of semiconductors has largely followed Moore's Law, which roughly states that the number of transistors in dense integrated circuits doubles about every two years. At present, semiconductor processes are developing toward below 28 nm, and some companies are embarking on 14 nm processes. Just to provide a reference here, a silicon atom is about 0.2 nm, which means that the distance between two separate components manufactured by a 28 nm process is about only one hundred and forty silicon atoms.

Semiconductor device manufacturing has therefore become increasingly challenging and advancing toward the physically possible limit. As the dimension of the ultra-large-scale integrated circuit continues to shrink, limitations in terms of the manufacture procedure and the material characteristics become increasingly significant. In the current 28 nm platform process, in order to reduce the parasitic capacitance of an MOS transistor gate and increase the speed of a device, a gate stack structure of a high-K gate dielectric layer and a metal gate is introduced into the MOS transistor. In a manufacture procedure for an HKMG (high-K metal gate), there are two existing manufacture processes for treatments of work function layers of metal gates for N-type and P-type devices. In the first manufacture process, work function layers of an N-type and a P-type device are treated separately; and in the second manufacture process, the use of photomask is reduced, and a work function layer of a P-type device is first generated, and then, corresponding to an N-type device, a work function layer of the N-type device is generated. Both processes can realize the manufacture of a 28 nm HKMG device, but from the perspective of being more competitive and capable of increasing the speed of the manufacture procedure, the second process is slightly better due to the reduced use of photomasks.

Nevertheless, when forming the HKMG device using the second process, for the P-type transistor, in addition to its own P-type work function layer, an N-type work function layer covers the P-type work function layer for the reason of the manufacture procedure. Due to environmental and temperature effects of different manufacture procedures, Al ions in the N-type work function layer on the P-type work function layer and in a top metal layer migrate to the bottom, affecting the stability of the electric characteristics and the yield rate of the P-type transistor.

Therefore, there is an urgent need for a transistor gate structure and a manufacturing method for the transistor gate structure, which can improve the migration of aluminum ions without increasing the number of used photomasks, and avoid affecting the characteristics of components due to thermal effects caused by different manufacture procedures, thereby avoiding a low yield rate.

### BRIEF SUMMARY OF THE DISCLOSURE

A brief summary on one or more embodiments are given below to provide the basic understanding for these embodiments. This summary is not an exhaustive overview of all the contemplated embodiments and are neither intended to indicate critical or decisive elements of all embodiments nor to attempt to define the scope of any or all embodiments. Its sole purpose is to present some concepts of one or more embodiments in a simplified form as a preface for a more detailed description presented later.

In order to solve the problem, in the second process, of affecting the electric characteristics of a P-type device due to the migration of aluminum ions, the present disclosure provides a transistor gate structure and a manufacturing method for the transistor gate structure, which can effectively alleviate the problem, in the manufacture process, of the migration of aluminum ions.

Specifically, the transistor gate structure provided in the present disclosure is located on a substrate, the gate structure being isolated from the substrate by a gate insulating layer, and the gate structure comprises a work function layer and a plurality of sets of composite barrier layers located between the work function layer and the gate insulating layer, and each set of the plurality of sets of composite barrier layers comprise laminated first and second barrier layers, the material of the first barrier layer being different from that of the second barrier layer.

In the gate structure as mentioned above, the first barrier layer is made from a TiN material, and the second barrier layer is made from a TaN material.

In the gate structure as mentioned above, the gate insulating layer is in physical contact with the first barrier layer, and the work function layer is in physical contact with the second barrier layer.

In the gate structure as mentioned above, the gate structure comprises three sets of composite barrier layers.

In the gate structure as mentioned above, the work function layer at least includes an N-type work function layer.

In the gate structure as mentioned above, corresponding to a P-type transistor, the work function layer further comprises a P-type work function layer, the P-type work function layer being located between the composite barrier layers and the N-type work function layer.

In the gate structure as mentioned above, the N-type work function layer is made from a TiAl material, and the P-type work function layer is made from a TiN material.

In the gate structure as mentioned above, the gate structure further comprises a metal gate layer, the metal gate layer being isolated from the work function layer by a top barrier layer.

In the gate structure as mentioned above, the metal gate layer is made from an Al material, and the top barrier layer is made from a TiN material.

In the gate structure as mentioned above, the gate insulating layer comprises an interlayer insulating layer and a high-K dielectric layer, the interlayer insulating layer being located between the substrate and the high-K dielectric layer.

The present disclosure further provides a manufacturing method for a transistor gate structure, comprising: providing a substrate; forming a gate insulating layer on the substrate; depositing a plurality of sets of composite barrier layers on the gate insulating layer, and each set of the plurality of sets of composite barrier layers comprise laminated first and second barrier layers, the material of the first barrier layer being different from that of the second barrier layer; forming a work function layer on the composite barrier layer; and forming a gate on the work function layer.

In the manufacturing method as mentioned above, the first barrier layer is made from a TiN material, and the second barrier layer is made from a TaN material.

In the manufacturing method as mentioned above, the gate insulating layer is in physical contact with the first barrier layer, and the work function layer is in physical contact with the second barrier layer.

In the manufacturing method as mentioned above, the transistor gate structure comprises three sets of composite barrier layers.

In the manufacturing method as mentioned above, the step of forming the work function layer further comprises: depositing at least an N-type work function layer on the surface of the composite barrier layers.

In the manufacturing method as mentioned above, corresponding to a P-type transistor, the step of forming the work function layer further comprises: forming a P-type work function layer on the surface of the composite barrier layers; and forming the N-type work function layer on the surface of the P-type work function layer.

In the manufacturing method as mentioned above, the N-type work function layer is made from a TiAl material, and the P-type work function layer is made from a TiN material.

In the manufacturing method as mentioned above, the manufacturing method further comprises: forming a top barrier layer on the surface of the work function layer; and forming a metal gate layer on the surface of the top barrier layer.

In the manufacturing method as mentioned above, the metal gate layer is made from an Al material, and the top barrier layer is made from a TiN material.

In the manufacturing method as mentioned above, the step of forming the gate insulating layer further comprises: forming an interlayer insulating layer on the substrate; and forming a high-K dielectric layer on the surface of the interlayer insulating layer.

According to the transistor gate structure and the manufacturing method for the transistor gate structure provided in the present disclosure, by forming a plurality of sets of alternately laminated first and second barrier layers, a superior barrier effect on the migration of aluminum ions can be achieved, thereby improving the stability of the electric characteristics of a device.

### BRIEF DESCRIPTION OF THE DRAWINGS

FIG. 1 shows the schematic diagram of a transistor gate structure provided in the present disclosure;

FIG. 2 shows the schematic diagram of an embodiment of a transistor gate structure provided in the present disclosure; and

FIGS. 3-9B are structural schematic diagrams in a manufacture procedure of an embodiment of the transistor gate structure provided in the present disclosure, and FIGS. 7A, 8A and 9A correspond to structural schematic diagrams of N-type transistors in this embodiment, and FIGS. 7B, 8B and 9B correspond to structural schematic diagrams of P-type transistors in this embodiment.

### BRIEF DESCRIPTION OF THE DRAWINGS

Substrate 100
Gate insulating layer 110
Interlayer insulating layer 111
High-K dielectric layer 112
Bottom barrier layer 113
Composite barrier block 120
First barrier layer 121
Second barrier layer 122
Work function layer 130
N-type work function layer 131
P-type work function layer 132
Gate layer 140
Dummy poly 141
Top barrier layer 142
Sidewall 150

### DETAILED DESCRIPTION OF THE DISCLOSURE

The present disclosure is described below in detail in conjunction with the accompanying drawings and particular embodiments. It is noted that the embodiments described in conjunction with the accompanying drawings and particular embodiments are merely exemplary, and should not be construed as any limitation on the scope of protection of the present disclosure.

The present disclosure relates to a semiconductor process and device. More specifically, an embodiment of the present disclosure provides a semiconductor device gate structure, and the gate structure is located on a substrate, the gate structure being isolated from the substrate by a gate insulating layer, and the gate structure comprises a work function layer and a plurality of sets of composite barrier layers located between the work function layer and the gate insulating layer. With the plurality of sets of composite barrier layers, the phenomenon of diffusion of aluminum ions in the gate can be effectively improved, so that the performance of the transistor device is more stable, and the yield rate is higher. The present disclosure also provides other embodiments.

Furthermore, an apparatus that is not expressly indicated in the claims as being used for performing a particular function, or any component as being used for performing a step of a particular function, should not be construed as a means or step provision as specified in 35 USC Section 112, Paragraph 6. In particular, the use of “step of . . . ” or “action of . . . ” in the claims herein does not indicate relating to the specifications in 35 USC § 112, Paragraph 6.

Note that when used, the flags left, right, front, back, top, bottom, front, back, clockwise, and counterclockwise are used for convenience purposes only and do not imply any specific fixed direction. In fact, they are used to reflect the relative position and/or direction between various parts of an object.

As used herein, the terms “over . . . ”, “under . . . ”, “between . . . and . . . ”, and “on . . . ” means the relative position of that layer relative to another layer. Likewise, for example, a layer that is deposited or placed over or under another layer may be in direct contact with another layer or there may be one or more intervening layers. In addition, a layer that is deposited or placed between layers may be in direct contact with the layers or there may be one or more intervening layers. In contrast, a first layer “on” a second layer is in contact with the second layer. In addition, a relative position of a layer relative to another layer is provided (assuming that film operations of deposition, modification, and removal are performed in relative to a starting substrate, without considering the absolute orientation of the substrate).

As mentioned above, in order to solve the problem, in the second process, of affecting the electric characteristics of a P-type device due to the migration of aluminum ions, the present disclosure provides a transistor gate structure and a manufacturing method for the transistor gate structure, which can effectively alleviate the problem, in the manufacture process, of the migration of aluminum ions.

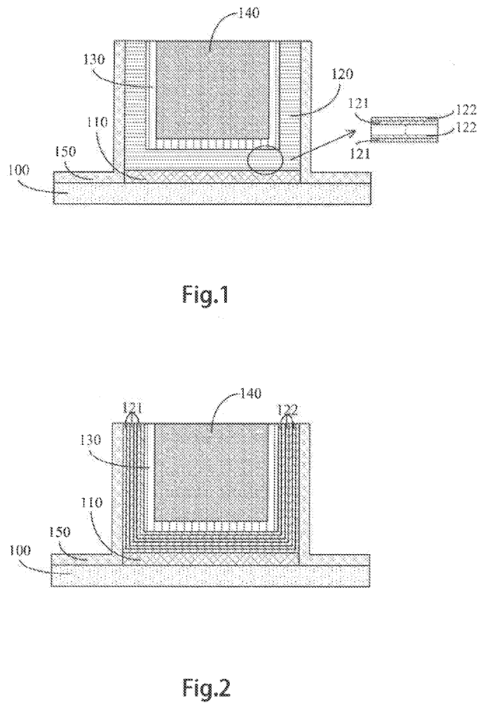

FIG. 1 shows the schematic diagram of a transistor gate structure provided in the present disclosure. As shown in FIG. 1, the transistor gate structure provided in the present disclosure is located on the substrate 100, and the substrate 100 may include: an elemental semiconductor including silicon or germanium in a crystalline, polycrystalline or amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; and any other suitable materials, or combinations of the foregoing. In an embodiment, the alloy semiconductor substrate 100 may have an SiGe feature of linear gradient compositions, and, from one position to another position, the compositions of Si and Ge are changed from one ratio to another ratio. In another embodiment, an SiGe alloy may be formed over a silicon substrate 100. In another embodiment, an SiGe substrate 100 may be strained. Furthermore, a semiconductor substrate 100 may be a semiconductor on an insulating layer, such as a silicon on insulator (SOI), or a thin film transistor (TFT). In some examples, the semiconductor substrate 100 may include a doped epi layer. In other examples, the compound semiconductor substrate 100 may have a multilayer structure, or the substrate 100 may include a multilayer compound semiconductor structure.

There is a gate insulating layer 110 on the substrate 100, and in this embodiment, the gate insulating layer 110 includes a high-K dielectric. The gate structure includes a gate layer 140 and a work function layer 130, and the work function layer 130 is isolated from the gate insulating layer 110 by the composite barrier block 120, the composite barrier block 120 comprising a plurality of sets of composite barrier layers, and each set of the plurality of sets of composite barrier layers comprise a first barrier layer 121 and a second barrier layer 122, the material of the first barrier layer 121 being different from that of the second barrier layer 122, and the first barrier layer 121 being in physical contact with the gate insulating layer 110, and the second barrier layer 122 being in physical contact with the work function layer 130.

In the above embodiment, the material of the first barrier layer 121 is TiN, and the material of the second barrier layer 122 is TaN.

In the above embodiment, the composite barrier block 120 comprises 3 sets of composite barrier layers, each set being composed of laminated first and second barrier layers 121 and 122, and FIG. 2 shows a structural schematic diagram of this embodiment.

In the manufacture procedure, the diffusion of aluminum ions from one medium to another needs to cross a potential barrier between the mediums and find lattice defects that allows the aluminum ions to pass through. Compared to a single set of superposed first barrier layer and second barrier layer, in the transistor gate structure provided in the present disclosure, by alternately laminating a plurality of sets of first and second barrier layers 121 and 122, aluminum ions have to cross a plurality of potential barriers during diffusion, thereby effectively reducing the diffusion of aluminum ions. In addition, the lattice directions of the plurality of alternately laminated barrier layers are different from one another, even if each single layer has lattice defects, the plurality of laminated composite barrier layers can effectively alleviate the problem of lattice defects, and make the structure of composite barrier layers to be dense, thereby effectively improving a downward diffusion and migration of aluminum ions from the gate layer 140.

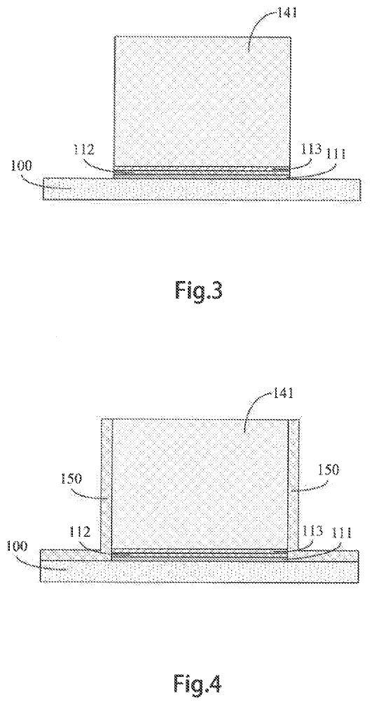

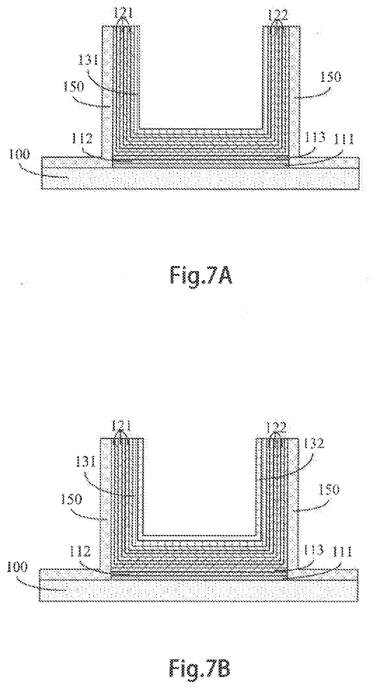

FIGS. 3-9B are structural schematic diagrams in a manufacture procedure of an embodiment of the transistor gate structure provided in the present disclosure, and FIGS. 7A, 8A and 9A correspond to structural schematic diagrams of N-type transistors in this embodiment, and FIGS. 7B, 8B and 9B correspond to structural schematic diagrams of P-type transistors in this embodiment. One embodiment of the manufacturing method provided in the present disclosure will be detailed below.

As shown in FIG. 3, a gate insulating layer and a dummy poly 141 on the gate insulating layer are formed on the substrate 100. Specifically, in this embodiment, the gate insulating layer comprises an interlayer insulating layer 111, a high-K dielectric layer 112, and a bottom barrier layer 113 formed on the substrate 100. The material of the bottom barrier layer 113 may be the same as that of the first barrier layer, that is, TiN. The bottom barrier layer 113, on one hand, allows the high-K dielectric layer to be protected in the preceding process, and on the other hand, in a subsequent generation of a gate, may be combined with a composite barrier block. In this embodiment, the material of the high-K dielectric layer 112 may be SiO2 or HfO2. The material of the dummy poly 141 may be a polysilicon material.

As shown in FIG. 4, sidewalls 150 are formed on both sides of the above dummy poly 141. After the sidewalls 150 are formed, a series of processes, such as ion implantation, on the semiconductor as needed, and the specific steps will not be described herein.

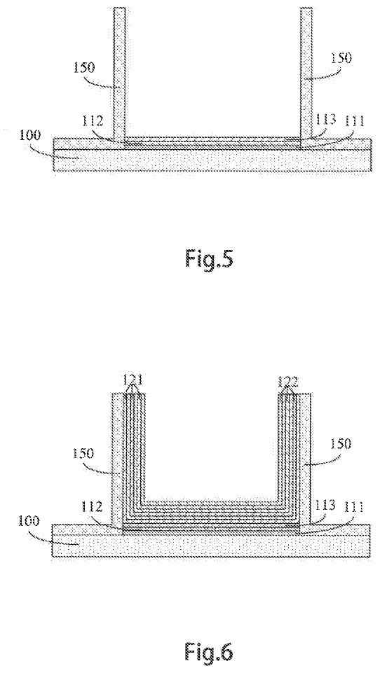

After the series of related processes are completed, as shown in FIG. 5, the dummy poly is removed to leave space for subsequent gate layers and barrier layers. FIG. 6 shows a structural schematic diagram of forming three sets of composite barrier layers, each set being composed of a first barrier layer 121 and a second barrier layer 122, in one embodiment. In one embodiment, the number of the composite barrier layers can be set as needed, including but not limited to the 3 sets as shown in the figure. The material of the first barrier layer 121 is different from that of the second barrier layer 122, and in one embodiment, the material of the first barrier layer 121 is TiN, and the material of the second barrier layer 122 is TaN.

After the formation of the composite barrier layers, the manufacturing method further comprises the step of forming a work function layer of a device on the composite barrier layer. Since different types of devices have different electric characteristics, the types of work function corresponding to different types of devices are also different. As described above, the common practice in the art at present is as follows: corresponding to an N-type device, the work function layer uses a TiAl material, and corresponding to a P-type device, the work function layer uses a TiN material. In addition, as described above, in order to reduce the number of used photomasks, the current common process is as follows: corresponding to an N-type and a P-type device, an N-type work function layer 131 is first formed on the surface of the barrier layer, and FIG. 7A shows a structural schematic diagram of the N-type or the P-type device after this step. Corresponding to the P-type device, it is also necessary to form a P-type work function layer 132 on the N-type work function layer 131, as shown in FIG. 7B.

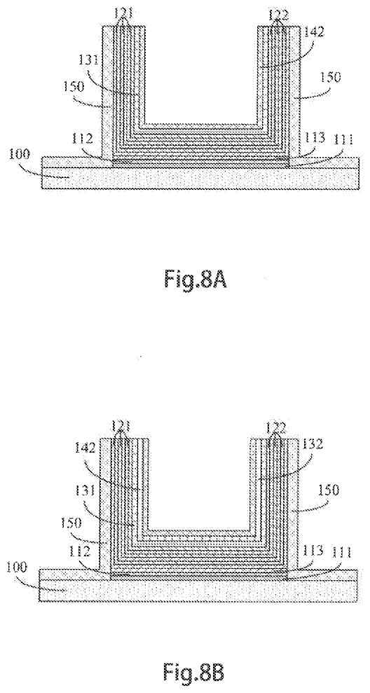

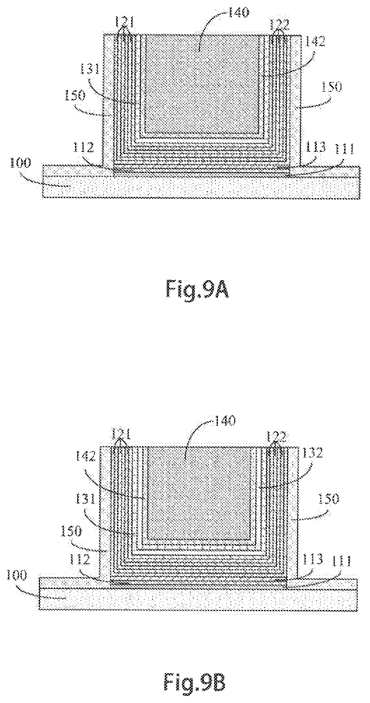

After the work function layer is formed, as shown in FIG. 8A or 8B, it is also necessary to form a top barrier layer 142 on the surface of the work function layer, and FIG. 8A shows a schematic diagram of the gate structure of the N-type device, and FIG. 8B shows a schematic diagram of the gate structure of the P-type device. In an embodiment, the material of the top barrier layer 142 is TiN. After the top barrier layer 142 is formed, the manufacturing method further comprises the step of forming the gate layer 140, as shown in FIG. 9A or 9B, and FIG. 9A shows a schematic diagram of the gate structure of the N-type device, and FIG. 9B shows a schematic diagram of the gate structure of the P-type device. Specifically, the gate layer 140 is a metal gate layer with a metal material of Al. In the above structure, the top barrier layer 142 isolates the work function layer from the metal gate layer, and can function to prevent the diffusion of Al.

The thermal effects of different manufacture procedures cause the Al within the HKMG device to diffuse downwards and combine with other element bonds to affect the electric characteristics of the device, especially for a PMOS device, Al ions easily pass through a cover layer and combine with HfO2 in the gate insulating layer, so that the performance of the PMOS device deteriorates. In the present disclosure, a multilayer dense structure is used to effectively alleviate the problem of Al penetration and diffusion, and alleviate the problem of deterioration of electric characteristics of PMOS due to different manufacture procedures. In addition, the manufacturing method provided in the present disclosure has a simple process and does not need addition of light covers, which results in an increase in cost, and at the same time, the manufacturing method does not need addition of steps of manufacture procedure, which results in more complexity; moreover, the manufacturing method improves the P-transistor device without affecting the performance of the N-transistor device.

Therefore, embodiments for manufacturing a transistor gate structure which improves the electric characteristics of P-type devices and a manufacturing method for the transistor gate structure have been described. Although the present disclosure has been described with respect to certain exemplary embodiments, it will be apparent that various modifications and changes may be made to these embodiments without departing from the more general spirit and scope of the disclosure. Accordingly, the specification and the accompanying drawings are to be regarded in an illustrative rather than a restrictive sense.

It is to be understood that this description is not intended to explain or limit the scope or meaning of the claims. In addition, in the detailed description above, it can be seen that various features are combined together in a single embodiment for the purpose of simplifying the disclosure. The method of the present disclosure should not be interpreted as reflecting the intention that the claimed embodiments require more features than those expressly listed in each claim. Rather, as reflected by the appended claims, an inventive subject matter lies in being less than all features of a single disclosed embodiment. Therefore, the appended claims are hereby incorporated into the detailed description, with each claim standing on its own as a separate embodiment.

One embodiment or embodiments mentioned in this description is/are intended to be, combined with a particular feature, structure, or characteristic described in the embodiment, included in at least one embodiment of a circuit or method. The appearances of phrases in various places in the specification are not necessarily all referring to a same embodiment.

What is claimed is:

1. A transistor gate structure, located on a substrate, the gate structure being isolated from the substrate by a gate insulating layer, wherein the gate structure comprises:
a work function layer and a plurality of sets of composite barrier layers located between the work function layer and the gate insulating layer, wherein each set of the composite barrier layers comprise stacked first and second barrier layers, the material of the first barrier layer being different from that of the second barrier layer.

2. The gate structure of claim 1, wherein the first barrier layer is made from a TiN material, and the second barrier layer is made from a TaN material.

3. The gate structure of claim 2, wherein the gate insulating layer is in physical contact with the first barrier layer, and the work function layer is in physical contact with the second barrier layer.

4. The gate structure of claim 1, wherein the gate structure comprises three sets of composite barrier layers.

5. The gate structure of claim 1, wherein the work function layer at least includes an N-type work function layer.

6. The gate structure of claim 5, wherein, corresponding to a P-type transistor, the work function layer further comprises a P-type work function layer, the P-type work function layer being located between the composite barrier layers and the N-type work function layer.

7. The gate structure of claim 6, wherein the N-type work function layer is made from a TiAl material, and the P-type work function layer is made from a TiN material.

8. The gate structure of claim 1, wherein the gate structure further comprises a metal gate layer, the metal gate layer being isolated from the work function layer by a top barrier layer.

9. The gate structure of claim 8, wherein the metal gate layer is made from an Al material, and the top barrier layer is made from a TiN material.

10. The gate structure of claim 1, wherein the gate insulating layer comprises an interlayer insulating layer and a high-K dielectric layer, the interlayer insulating layer being located between the substrate and the high-K dielectric layer.

11. A manufacturing method for a transistor gate structure, comprising:
providing a substrate;
forming a gate insulating layer on the substrate;
depositing a plurality of sets of composite barrier layers on the gate insulating layer, wherein each set of the composite barrier layers comprise stacked first and second barrier layers, the material of the first barrier layer being different from that of the second barrier layer;
forming a work function layer on the composite barrier layers; and
forming a gate on the work function layer.

12. The manufacturing method of claim 11, wherein the first barrier layer is made from a TiN material, and the second barrier layer is made from a TaN material.

13. The manufacturing method of claim 12, wherein the gate insulating layer is in physical contact with the first barrier layer, and the work function layer is in physical contact with the second barrier layer.

14. The manufacturing method of claim 11, wherein the transistor gate structure comprises three sets of composite barrier layers.

15. The manufacturing method of claim 11, wherein the step of forming the work function layer further comprises: depositing at least an N-type work function layer on the surface of the composite barrier layers.

16. The manufacturing method of claim 15, wherein, corresponding to a P-type transistor, the step of forming the work function layer further comprises:
forming a P-type work function layer on the surface of the composite barrier layers; and
forming the N-type work function layer on the surface of the P-type work function layer.

17. The manufacturing method of claim 16, wherein the N-type work function layer is made from a TiAl material, and the P-type work function layer is made from a TiN material.

18. The manufacturing method of claim 11, wherein the manufacturing method further comprises: forming a top barrier layer on the surface of the work function layer; and
forming a metal gate layer on the surface of the top barrier layer.

19. The manufacturing method of claim 18, wherein the metal gate layer is made from an Al material, and the top barrier layer is made from a TiN material.

20. The manufacturing method of claim 11, wherein the step of forming the gate insulating layer further comprises:
forming an interlayer insulating layer on the substrate; and
forming a high-K dielectric layer on the surface of the interlayer insulating layer.
